(19) United States
(12) Patent Application Publication
(10) Pub. No.: US 2026/0288011 A1
(43) Pub. Date: Sep. 24, 2026

(54) COMPOSITIONS CONTAINING N-SUBSTITUTED PIPERAZINES FOR ELECTRONIC MANUFACTURING APPLICATIONS

(71) Applicant: Dow Global Technologies LLC, Midland, MI (US)

(72) Inventors: Qi Jiang, Shanghai (CN); Xue Chen, Manvel, TX (US)

(21) Appl. No.: 19/469,961

(22) PCT Filed: Jun. 5, 2023
(86) PCT No.: PCT/CN2023/098234

§ 371 Date: Sep. 26, 2025

(51) Int. Cl. G03F 7/42; C08K 5/3462

(52) U.S. Cl. CPC G03F 7/425; C08K 5/3462

(57) ABSTRACT

A composition comprising at least the following components a), b) and c): a) at least one N-substituted piperazine selected from the following: Structure (1) as described herein, Structure (2) as described herein, or a mixture thereof; b) at least one glycol ether selected from the following Structures (3) as described herein, Structure (4) as described herein or a mixture thereof; and c) water.

### BACKGROUND OF THE INVENTION

Organic amines are widely used in stripping and cleaning formulations for electronics processing. For example, such amines are used in photoresist stripper formulations for preparing RGB (red, green, blue) dyes in displays, and in photoresist stripper formulations for lithography as applied in semiconductor manufacturing. The organic amines can provide excellent dissolution of many polar polymers, monomers, and compounds. In the industry, MIPA (monoisopropanolamine) or AEEA (aminoethylethanolamine) are typical amines in photoresist stripper formulations; however these formulations can cause severe metal corrosion and their stripping performance is not good at lower dosages of the amine. The dosage of the organic amine, in general electronics processing formulations, is typically greater than 10 wt %, to improve the dissolution of polar polymers, monomers and compounds. More commonly, the dosage of the organic amine is targeted around 20 wt %. However, such high concentrations of the organic amine, not only increases the cost of the formulation, but also increases the cost of the waste treatment of the formulation. There is a need for photoresist stripper compositions containing low dosages of amine, and which provide good stripping capability and low metal corrosion.

U.S. Pat. No. 7,888,301 discloses an aqueous-based composition and process for removing a photoresist, a bottom anti-reflective coating (BARC) material, and/or a gap fill material, from a substrate having such material(s) thereon. The aqueous-based composition includes a fluoride source, at least one organic amine, at least one organic solvent (for example, a diol, a glycol or a glycol ether, each as described therein), water, and optionally a chelating agent and/or a surfactant. See abstract. The composition is disclosed as achieving a high-efficiency removal of such material(s) in the manufacture of integrated circuitry, without an adverse effect on the metal species on the substrate, such as copper, and without damage to the SiOC-based dielectric materials employed in the semiconductor architecture. See abstract. Preferred organic amines include, but are not limited to, hydroxyethyl-piperazine (HEP), hydroxypropylpiperazine (HPP), aminoethylpiperazine (AEP), aminopropylpiperazine (APP), hydroxyethylmorpholine (HEM), hydroxypropylmorpholine (HPM), aminoethylmorpholine (AEM), aminopropylmorpholine (APM), triethanolamine (TEA), pentamethyldiethylenetriamine (PMDETA), dimethylaminoethoxyethanol (DMAEE), aminoethoxyethanol (AEE), ethylene urea (EU), trimethylaminoethylethanolamine (TMAEEA), trimethylaminopropylethanolamine (TMAPEA), N-(2-cyanoethyl) ethylenediamine (CEEDA), and N-(2-cyanopropyl) ethylenediamine (CPEDA). Particularly preferred organic amines include ethylene urea, hydroxyethyl-morpholine, and N-(2-cyanoethyl) ethylenediamine. See column 4, line 56, to column 5, line 3. See also, column 5, lines 4-17.

KR102057158B1 (machine translation) discloses a photoresist stripper composition comprising N,N-dimethyl propionamide, which can replace solvents such as NMP, which are harmful to the human body. See abstract. The composition may contain a cyclic amine, for example, from 1-(2-hydroxyethyl) piperazine, 1-(2-aminoethyl) piperazine, 1-(2-hydroxy-ethyl) methylpiperazine, N-(3-aminopropyl). See Description section. The composition may contain a proton polar solvent, such as a glycol or a glycol ether, each as described therein. See Description section.

KR20180120397A (machine translation) discloses a photoresist stripping liquid composition comprising a cyclodextrin or a derivative thereof. See abstract. The composition may contain an organic basic compound selected from the group consisting of monomethyl-amine, dimethylamine, triethylamine, diisopropylethylamine, monoethanol-amine, mono-isopropanol, diethanolamine, triethanolamine, 2-(2-aminoethoxy)(2-hydroxy-ethyl) piperazine, 1-(2-aminoethyl) piperazine, 1-2-methylpiperazine, 1-amino-4-methyl-piperazine, 1-benzyl-piperazine, 1-phenyl-(2-methylpiperazin-1-yl), one selected from the group consisting of piperazine, tetramethylguanidine, 1,8-diazabicycloundec-7-ene, and 1,5-diazabicyclo (4,3,0). See Description section. The composition may contain a polar solvent, such as an amide or a glycol ether, each as described herein. See Description section.

KR101221560B1 (machine translation) discloses a photoresist stripper composition comprising: (a) 0.1 to 10 weight percent of hydrogen peroxide or a hydrogen peroxide derivative, (b) 5 to 50 weight percent of an organic solvent, (c) 0.5 to 30 weight percent of an organic amine, (d) 5 to 60 weight percent water, (e) 0.0001 to 20 weight percent of an ammonium salt, (f) 0.4 to 10 weight percent of an corrosion inhibitor, and (g) 0.5 to 30 weight percent of a stabilizer of hydrogen peroxide or hydrogen peroxide derivative. See Abstract. The organic amine compound is monoethanolamine, isopropanolamine, aminoethoxy ethanol, n-methyl-ethanolamine, dimethylethanolamine, diethylethanolamine, 2-aminoethylaminoethanol, aminoethylpiperazine, aminopropylpiperazine, hydroxyethyl-piperazine, 1-amino-4-methyl-piperazine, 2-methylpiperazine, 1-methylpiperazine, 1-benzylpiperazine, 2-phenyl-piperazine, 1-aminoethylpiperazine. See Description section. The organic solvent (b) is water-soluble, and may be dimethylsulfoxide (DMSO), N-methylpyrrolidone (NMP), dimethylacetamide (DMAc), dimethylformamide (DMF), and dimethylimizolidone (DMI). See Description section.

CN104781732B (machine translation) discloses a photoresist stripping composition and method, disclosed as providing a photoresist stripping effect and a corrosion prevention effect (see abstract). The stripping composition contains N,N-dimethylpropionamide, Solketal, and an organic amine. The composition is disclosed as replacing glycol ether compounds. See abstract. The organic amine includes one or more compounds selected from the group consisting of monoethanolamine (MEA), ethylenediamine, 2-(2-aminoethoxy) ethanol, 2-(2-aminoethylamino) ethanol, 1-amino-2-propanol, diethanolamine, iminodipropionic amine, 2-methylaminoethanol, methyldiethanol-amine, triethylaminoethanol, 1-(2-hydroxyethyl) piperazine (HEP), 1-(2-aminoethyl) piperazine, 1-(2-hydroxyethyl) methylpiperazine, N-(3-aminopropyl) morpholine, 2-methylpiperazine, 1-amino-4-methylpiperazine, 1-benzylpiperazine, and 1-phenylpiperazine (see claim 2).

CN104216242A (machine translation) discloses a stripping composition used for color photoresist and an organic insulating film (see abstract). The stripping composition comprises a quaternary ammonium compound; a polar solvent; an alkylamine; a amine compound of formula 1, as described therein, or of formula 2, as described therein; an inorganic alkali or salt thereof; and water. See abstract. The amines of formula 2 are selected from least one of the following: piperazine, N-methyl piperazine, NEP, N-vinyl piperazine, N-vinyl methyl piperazine, N-vinyl ethyl piperazidine, N-vinyl-N′-methyl piperazine, N-acryloylpiperazines, N-acryloyl group-N′-methyl piperazine, hydroxyethyl piperazine, N-(2-amino-ethyl) piperazine, N,N′-dimethyl piperazine, morpholine, N-methylmorpholine, N-ethylmorpholine, N-phenyl-morpholine, N-polyvinyl morpholinone, N-vinyl methyl morpholine, N-vinyl ethyl morpholine, N-acryloyl morpholine, N-cocoa morpholine, N-(2-amino-ethyl) morpholine, N-(2-cyanoethyl) morpholine, N-(2-hydroxyethyl) morpholine, N-(2-hydroxypropyl) morpholine, N-acetylmorpholine and N-formyl morpholine (see claim 6). The polar solvent may be a sulfur-bearing molecule (see Embodiment section).

TW201732461A (machine translation) discloses a photoresist peeling agent composition. Such composition is disclosed as able to remove a photoresist and to avoid corrosion of the metal pattern and/or damage to the organic/inorganic film. See abstract. The photoresist peeling agent composition includes, relative to the total weight of the peeling agent composition, an aprotic polar solvent of 15% to 80% by weight having N,N-dimethyl-propanamide; a proton polar solvent of 25% to 80% by weight; and an amine compound of 1% to 15% by weight. See abstract. The amine compound is one or more selected from monoethanolamine, diethanolamine, triethanolamine, glycolamine, diglycolamine, monoisopropanolamine, 2-(2-aminoethoxy)-ethanol, amine ethylethanol, 1-(2-hydroxyethyl)piperazine, 1-(2-aminoethyl) piperazine, pyrazine, 1-(2-hydroxyethyl)methylpiperazine, 1-methylpiperazine, 2-methylpiperazine, and 1-amino-4-methylpiperazine. See claim section and the Description section. The protic polar solvent may be a glycol or a glycol ether, each as described herein (see, for example, the Claim section).

KR20130007402A (machine translation) discloses a cleaning liquid composition comprising 0.05 to 10% by weight of a cyclic amine, 0.1 to 20% by weight of a water-soluble glycol ether compound, and 79 to 99.5% by weight of water, based on the total weight of the composition. See abstract and claim 1. Cyclic amine compounds represented by Formula 1, as described therein, include N-methylmorpholine, N-ethylmorpholine, N-formylmorpholine, N-(2-hydroxyethyl) morpholine, and N-(3-hydroxy propyl) morpholine, N-(2-hydroxyethyl)-N′-methylpiperazine, N-(2-hydroxyethyl)-N′-ethylpiperazine, N,N′-bis(2-hydroxyethyl) piperazine and the like. These compounds may be used alone or in combination of two or more. See Description section. Specific examples of the water-soluble glycol ether compound include ethylene glycol monobutyl ether (BG), ethylene glycol monopropyl ether, diethylene glycol monomethyl ether (MDG), diethylene glycol monoethyl ether, diethylene glycol monobutyl ether (BDG), dipropylene glycol monomethyl ether (DPM), dipropylene glycol monoethyl ether (MFDG), triethylene glycol monobutyl ether (BTG), triethylene glycol monoethyl ether (MTG), propylene glycol monomethyl ether (MFG), propylene glycol monopropyl ether, and the like, and these may be used alone or in combination of two or more thereof. See Description section.

WO02/084401A2 discloses photoresists that are suitable for short wavelength imaging. The resists comprise a fluorine-containing polymer, a photoactive component, and a solvent component (see abstract). The photoresists may contain a basic additive. Basic additives include DBU (1,8-diazobicyclo[5.4.0]undec-7-ene); DBN (1,5-diaza-bicyclo[4.3.0]non-5-ene; N,N-bis-(2-hydroxyethyl)piperazine; N,N-bis-(2-hydroxyethyl)-2,5-diazobicyclo[2.2.1]heptane; N-triisopropanolamine; dibutyl amine, branched isomers thereof, such as diisobutylamine and ditertbutylamine; .tributyl amine, branched isomers thereof, such as ditertbuylamine and tritertbutylamine; and the like. Optionally substituted piperidine and other optionally piperazine compounds are also disclosed as suitable, particularly hydroxy-substituted or (C₁-C₁₂)-alcohol-substituted piperidines and piperazines, such as N-ethanol piperidine and N-diethanol piperazine (see pages 26-27).

However, as discussed above, there remains a need for electronic stripper compositions containing low dosages of amine, and which provide good stripping capability and low metal corrosion. This need has been met by the following invention.

### SUMMARY OF THE INVENTION

A composition comprising at least the following components a), b) and c):
a) at least one N-substituted piperazine selected from the following Structures 1, 2 or a mixture thereof:

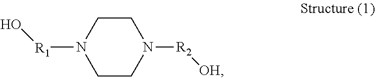

wherein R1 and R2 are each independently a C1-C6 alkylene;

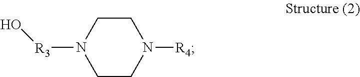

wherein R3 is a C1-C6 alkylene and R4 is a C1-C6 alkyl
b) at least one glycol ether selected from the following Structures 3, 4 or a mixture thereof:

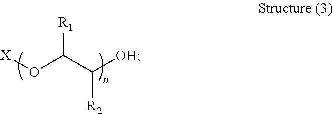

wherein n≥1; R1 is hydrogen or an alkyl; R2 is hydrogen or an alkyl; X is hydrogen or an alkyl or an aryl, when n>1; and X is an alkyl or an aryl, when n=1;

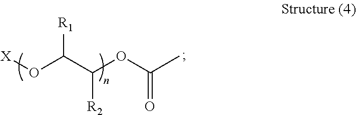

wherein n≥1; R1 is hydrogen or an alkyl; R2 is hydrogen or an alkyl; X is hydrogen or an alkyl or an aryl, when n>1; and X is an alkyl or an aryl, when n=1;
c) water.

### BRIEF DESCRIPTION OF THE DRAWINGS

FIG. 1 is a plot of the boiling point of 1,4-bis(2-hydroxyethyl)piperazine as a function of “mm Hg.” The equation of the profile is y=26.385 ln(x)+118.53 (R²=0.9616).

### DETAILED DESCRIPTION OF THE INVENTION

New photoresist stripping compositions have been discovered that provide excellent photoresist dissolution and stripping efficiency, without significant metal corrosion. These compositions may also contain relatively low dosages of organic amine. As discussed above, a composition is provided, which comprises at least the following components a, b and c, each as described herein.

The above composition may comprise a combination of two or more embodiments, as described herein. Component a may comprise a combination of two or more embodiments, as described herein. Component b may comprise a combination of two or more embodiments, as described herein. Each structure, Structure 1, Structure 2, Structure 3 and Structure 4, may, independently, comprise a combination of two or more embodiments, as described herein. As used herein, in regard to Structure 1, R1=R₁ and R2=R₂; Structure 2, R3=R₃ and R4=R₄; Structure 3, R1=R₁ and R2=R₂; and Structure 4, R1=R₁ and R2=R₂ Note, Structure 1 refers to Structure (1), and the same for Structures 2, 3 and 4.

In one embodiment, or a combination of two or more embodiments, each described herein, for component a, Structure 1 or Structure 2, each independently has a boiling point (at 760 mm Hg)≥250° C., or ≥251° C., or ≥252° C., or ≥253° C., or ≥254° C., or ≥255° C. In one embodiment, or a combination of two or more embodiments, each described herein, for component a, Structure 1 or Structure 2, each independently has a boiling point (at 760 mm Hg)≤350° C., or ≤345° C., or ≤340° C., or ≤335° C., or ≤330° C., or ≤325° C., or ≤320° C., or ≤315° C., or ≤310° C., or ≤308° C., or ≤307° C., or ≤306° C., or ≤305° C., or ≤304° C., or ≤303° C., or ≤302° C.

In one embodiment, or a combination of two or more embodiments, each described herein, the ratio of the boiling point (760 mm Hg) of Structure 1 or Structure 2 of component a to the boiling point (760 mm Hg) of Structure 3 or Structure 4 of component b, is each, independently, ≥0.70, or ≥0.72, or ≥0.75, or ≥0.78, or ≥0.80, or ≥0.82, or ≥0.85, or ≥0.88, or ≥0.90, or ≥0.92, or ≥0.94, or ≥0.96, or ≥0.98, or ≥1.0, or ≥1.1. In one embodiment, or a combination of two or more embodiments, each described herein, the ratio of the boiling point (760 mm Hg) of Structure 1 or Structure 2 of component a to the boiling point (760 mm Hg) of Structure 3 or Structure 4 of component b, is each, independently, ≤1.9, or ≤1.8, or ≤1.7, or ≤1.6, or ≤1.5 or ≤1.4, or ≤1.3.

In one embodiment, or a combination of two or more embodiments, each described herein, for component a, Structure 1, R1=R2.

In one embodiment, or a combination of two or more embodiments, each described herein, component a is selected from Structures 1a), 2a) or 3aa), each as shown below:

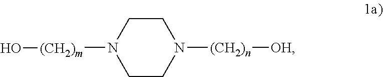

wherein n is an integer from 1 to 6, further from 1 to 5, further from 1 to 4, further from 2 to 4, further from 2 to 3, further 2; and m is an integer from 1 to 6, further from 1 to 5, further from 1 to 4, further from 2 to 4, further from 2 to 3, further 2; and further n=m;

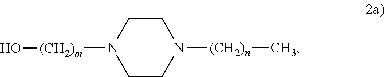

wherein n is an integer from 0 to 5, further from 0 to 4, further from 0 to 3, further from 0 to 2, further from 0 to 1, further 0; and m is an integer from 1 to 6, further from 1 to 5, further from 1 to 4, further from 2 to 4, further from 2 to 3, further 3; or
3aa) a mixture of Structure 1a) and Structure 2a).

In one embodiment, or a combination of two or more embodiments, each described herein, component a is selected from Structure 1a), as shown above, and further n=m, further n=m=2 or 3, further n=m=2.

In one embodiment, or a combination of two or more embodiments, each described herein, component a is selected from Structure 2a), as shown above, and further n=0 or 1, further n=0; and further m=2 or 3, further m=3.

In one embodiment, or a combination of two or more embodiments, each described herein, component a is selected from Structure 3aa), as shown above.

In one embodiment, or a combination of two or more embodiments, each described herein, for component b, Structure 3 and Structure 4, each n is independently from 1 to 10, further from 1 to 8, further from 1 to 6, further from 1 to 4, further from 2 to 4, further from 2 to 3, further 2.

In one embodiment, or a combination of two or more embodiments, each described herein, for component b, Structure 3 and Structure 4, each X is independently an alkyl, and further a C1-C6 alkyl, further a C1-C5 alkyl, further a C2-C5 alkyl, further a C2-C4 alkyl, further a C3-C4 alkyl, further a C4 alkyl.

In one embodiment, or a combination of two or more embodiments, each described herein, for component b, Structure 3 and Structure 4, each R1 and R2 independently meet the following relationship: R1=R2, and further R1=R2=H.

In one embodiment, or a combination of two or more embodiments, each described herein, component b is selected from Structure (3a) below:

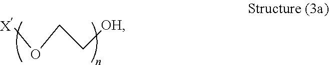

wherein n≥1; and X′ is hydrogen or an alkyl, when n>1; and X′ is an alkyl, when n=1. In a further embodiment, X′ is an alkyl.

In one embodiment, or a combination of two or more embodiments, each described herein, component b is selected from Structure (4a) below:

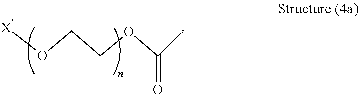

wherein n≥1; and X′ is hydrogen or an alkyl, when n>1; and X′ is an alkyl, when n=1. In a further embodiment, X′ is an alkyl.

In one embodiment, or a combination of two or more embodiments, each described herein, the weight ratio of component a to component b is ≥0.40, or ≥0.45, or ≥0.50, or ≥0.55, or ≥0.60, or ≥0.65. In one embodiment, or a combination of two or more embodiments, each described herein, the weight ratio of component a to component b is ≤1.00, or ≤0.95, or ≤0.90, or ≤0.85, or ≤0.80, or ≤0.75, or ≤0.70.

In one embodiment, or a combination of two or more embodiments, each described herein, the weight ratio of component c to component a is ≥2.0, or ≥2.5, or ≥3.0, or ≥4.0, or ≥4.5, or ≥5.0, or ≥5.2, or ≥5.4, or ≥5.6. In one embodiment, or a combination of two or more embodiments, each described herein, the weight ratio of component c to component a is ≤8.0, or ≤7.5, or ≤7.0, or ≤6.8, or ≤6.6, or ≤6.4, or ≤6.2, or ≤6.0, or ≤5.9, or ≤5.8.

In one embodiment, or a combination of two or more embodiments, each described herein, the weight ratio of component c to component b is ≥1.0, or ≥1.5, or ≥2.0, or ≥2.5, or ≥3.0, or ≥3.2, or ≥3.4, or ≥3.6, or ≥3.7, or ≥3.8. In one embodiment, or a combination of two or more embodiments, each described herein, the weight ratio of component c to component b is ≤5.0, or ≤4.8, or ≤4.6, or ≤4.4, or ≥4.2, or ≤4.1, or ≤4.0.

In one embodiment, or a combination of two or more embodiments, each described herein, the sum of component a and component b is present in an amount ≥15 wt %, or 18 wt %, or ≥20 wt %, or 22 wt %, or ≥24 wt %, or ≥25 wt %, or ≥26 wt %, or ≥27 wt %, or ≥28 wt %, or ≥30 wt %, or ≥31 wt %, or ≥32 wt % based on the weight of the composition. In one embodiment, or a combination of two or more embodiments, each described herein, the sum of component a and component b is present in an amount ≤50 wt %, or ≤48 wt %, or ≤45 wt % or ≤42 wt %, or ≤40 wt %, or ≤38 wt %, or ≤36 wt %, or ≤34 wt %, based on the weight of the composition.

In one embodiment, or a combination of two or more embodiments, each described herein, the sum of components a, b and c is present in an amount ≥90 wt %, or 92 wt %, or ≥94 wt %, or ≥96 wt %, based on the weight of the composition. In one embodiment, or a combination of two or more embodiments, each described herein, the sum of components a, b and c is present in an amount ≤100 wt %, or ≤99 wt %, or ≤98 wt %, based on the weight of the composition.

In one embodiment, or a combination of two or more embodiments, each described herein, the composition has an “a photoresist removal time”≤50 sec, or ≤49 sec, or ≤48 sec, or ≤47 sec, or ≤46 sec, or ≤45 sec (see experimental section, no aging of the composition). In one embodiment, or a combination of two or more embodiments, each described herein, the composition has an “a Cu ion concentration”≤1.2 ppm, or ≤1.1 ppm, or ≤1.0 ppm, or ≤0.90 ppm, or ≤0.80, ppm, or ≤0.60 ppm, or ≤0.40 ppm, or ≤0.30 ppm, or ≤0.20 ppm (see experimental section—corrosion test, 54° C. for 30 minutes, no aging of the composition).

In one embodiment, or a combination of two or more embodiments, each described herein, the composition is a photoresist stripping composition.

Also provided is a process to form the composition of any one embodiment, or a combination of two or more embodiments, each as described herein, the process comprising mixing at least components a and b.

Also provided is a process to remove a photoresist, the process comprising applying to the surface the photoresist the composition of any one embodiment, or a combination of two or more embodiments, each as described herein. In one embodiment, or a combination of two or more embodiments, each as described herein, the photoresist is coated onto a metal surface.

Component a—N-Substituted Piperazine

Component a is described herein. Syntheses of N-substituted piperazines are known in the art, and various ether amines are also commercially available. For example, the N-substituted piperazines can be generated by reacting the oxides with the piperazine. Further as an example, 1,4-bis(2-hydroxyethyl)piperazine can be synthesized by reacting the EO (ethylene oxide) and the piperazine at the targeted ratio of 2:1. This N-substituted piperazine can be recovered using conventional technologies. Note, the term N-substituted piperazine, as used herein, refers to an N-substitution and an N,N′-substitution on the piperazine ring.

Component a can be in the form of a liquid composition that is added to an aqueous composition. The N-substituted piperazine per se can be in the form of a liquid at room temperature (22° C.), and therefore a “stock” composition can be one where the N-substituted piperazine is in neat form (100 wt %). A stock composition can also be prepared with the N-substituted piperazine in one or more compatible solvents, such as, for example, where the N-substituted piperazine is present in an amount in the range of about 30% (wt) to about 99% (wt). The solvent may be water. The N-substituted piperazine may be in the form of a solid composition, such as in powder or granule form that can be added to an aqueous composition.

Component b—Glycol Ether

Component b is described herein. In one embodiment, component b is selected from ethylene glycol butyl ether; diethylene glycol methyl ether; diethylene glycol ethyl ether; diethylene glycol propyl ether; diethylene glycol butyl ether; ethylene glycol butyl ether acetate; diethylene glycol butyl ether acetate; propylene glycol methyl ether; propylene glycol methyl ether acetate.

### Other Additives

A composition, as described herein, may optionally include one or more additional additive(s). Examples of additives include, but are not limited to, corrosion inhibitors, antioxidants, surfactants, polar aprotic solvent and combinations thereof. Polar aprotic solvents may be selected from N-methyl-2-pyrrolidone; N-alkyl-2-pyrrolidone; dimethyl sulfoxide; N,N-dimethyl formamide; N,N-dimethyl acetamide; N,N-dimethyl alkylamide; and γ-butyrolactone. An additive may be present in an amount of ≥0.01 wt %, or ≥0.02 wt %, or ≥0.05 wt %, or ≥0.10 wt %, or ≥0.20 wt %, or ≥0.40 wt %, or ≥0.60 wt %, or ≥0.80 wt %, and/or ≤20 wt %, or ≤10 wt %, or ≤5.0 wt %, or ≤3.0 wt %, or ≤2.0 wt %, or ≤1.0 wt %, based on the weight of the composition.

### Definitions

Unless stated to the contrary, implicit from the context, or customary in the art, parts and percents are based on weight, and all test methods are current as of the filing date of this disclosure.

The term “composition,” as used herein, includes a mixture of materials, which comprise the composition, as well as reaction products and decomposition products formed from the materials of the composition. Any reaction product or decomposition product is typically present in trace or residual amounts.

The term “polymer,” as used herein, refers to a polymeric compound prepared by polymerizing monomers, whether of the same or a different type. The generic term polymer thus includes the term homopolymer (employed to refer to polymers prepared from only one type of monomer, with the understanding that trace amounts of impurities can be incorporated into the polymer structure), and the term interpolymer as defined hereinafter. Trace amounts of impurities, such as catalyst residues, can be incorporated into and/or within the polymer. Typically, a polymer is stabilized with very low amounts (“ppm” amounts) of one or more stabilizers.

The term “interpolymer,” as used herein, refers to a polymer prepared by the polymerization of at least two different types of monomers. The term interpolymer thus includes the term copolymer (employed to refer to polymers prepared from two different types of monomers) and polymers prepared from more than two different types of monomers.

The term “water,” as used herein, refers to an H₂O or an H₂O sample. Such a water (H₂O) sample is virtually pure water, and as such, may or may not contain one or more impurities, such as, for example, dissolved inorganic ions. Typically, the impurities are present in an amount ≤1000 ppm, preferably ≤100 ppm, more preferably ≤10 ppm, more preferably ≤1 ppm, based on the weight of the water sample.

The term “photoresist,” as used herein, refers to a light sensitive (for example, UV light) material used to form a patterned coating on a surface, such as, for example, a metal surface.

The phrase “applying to the surface of the photoresist” in reference to the process of removing a photoresist with a composition, described herein, refers to the act of contacting the surface with the composition. This contact may occur by wetting the photoresist surface with the composition using a spray, a brush, a roller, or by dipping the photoresist into the composition or by immersing the photoresist into the composition, or by any other means known in the art.

The terms “comprising,” “including,” “having,” and their derivatives, are not intended to exclude the presence of any additional component, step or procedure, whether the same is specifically disclosed. In order to avoid any doubt, all compositions claimed through use of the term “comprising” may include any additional additive, adjuvant, or compound, whether polymeric or otherwise, unless stated to the contrary. In contrast, the term, “consisting essentially of” excludes from the scope of any succeeding recitation any other component, step or procedure, excepting those that are not essential to operability. The term “consisting of” excludes any component, step or procedure, not specifically delineated or listed.

The term “stripping,” as used herein, refers to the removal of the photoresist. See for example, the experimental section.

### Listing of Some Composition and Process Features

A] A composition comprising at least the following components a), b) and c):
a) at least one N-substituted piperazine selected from the following Structures 1, 2 or a mixture thereof:

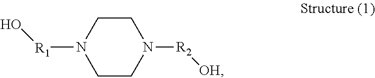

wherein R1 and R2 are each independently a C1-C6 alkylene;

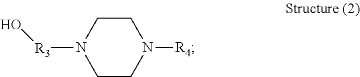

(2); wherein R3 is a C1-C6 alkylene and R4 is a C1-C6 alkyl
b) at least one glycol ether selected from the following Structures 3, 4 or a mixture thereof:

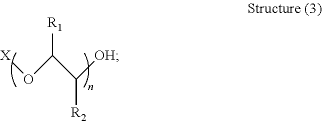

wherein n≥1; R1 is hydrogen or an alkyl; R2 is hydrogen or an alkyl; X is hydrogen or an alkyl or an aryl, when n>1; and X is an alkyl or an aryl, when n=1;

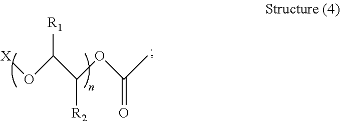

wherein n≥1; R1 is hydrogen or an alkyl; R2 is hydrogen or an alkyl; X is hydrogen or an alkyl or an aryl, when n>1; and X is an alkyl or an aryl, when n=1;
c) water.
   B] The composition of A] above, wherein for component a, Structure 1 or Structure 2, each independently has a boiling point (at 760 mm Hg)≥250° C., or ≥251° C., or ≥252° C., or ≥253° C., or ≥254° C., or ≥255° C.
   C] The composition of A] or B] above, wherein for component a, Structure 1 or Structure 2, each independently has a boiling point (at 760 mm Hg)≤350° C., or ≤345° C., or ≤340° C., or ≤335° C., or ≤330° C., or ≤325° C., or ≤320° C., or ≤315° C., or ≤310° C., or ≤308° C., or ≤307° C., or ≤306° C., or ≤305° C., or ≤304° C., or 303° C., or ≤302° C.
   D] The composition of any one of A]-C] (A] through C]) above, wherein the ratio of the boiling point (760 mm Hg) of Structure 1 or Structure 2 of component a to the boiling point (760 mm Hg) of Structure 3 or Structure 4 of component b, is each, independently, ≥0.70, or ≥0.72, or ≥0.75, or ≥0.78, or ≥0.80, or ≥0.82, or ≥0.85, or ≥0.88, or ≥0.90, or ≥0.92, or ≥0.94, or ≥0.96, or ≥0.98, or ≥1.0, or ≥11.
   E] The composition of any one of A]-D] above, wherein the ratio of the boiling point (760 mm Hg) of Structure 1 or Structure 2 of component a to the boiling point (760 mm Hg) of Structure 3 or Structure 4 of component b, is each, independently, ≤1.9, or ≤1.8, or ≤1.7, or ≤1.6, or ≤1.5 or ≤1.4, or ≤1.3.
   F] The composition of any one of A]-E] above, wherein, for component a, Structure 1, R1=R2.
   G] The composition of any one of A]-F] above, wherein, for component a, Structure 1, R1 is a C1-C5 alkylene, further a C1-C4 alkylene, further a C1-C3 alkylene, further a C1-C2 alkylene, further a C2 alkylene.
   H] The composition of any one of A]-G] above, wherein, for component a, Structure 1, R2 is a C1-C5 alkylene, further a C1-C4 alkylene, further a C1-C3 alkylene, further a C1-C2 alkylene, further a C2 alkylene.
   I] The composition of any one of A]-H] above, wherein, for component a, Structure 2, R3 is a C1-C5 alkylene, further a C1-C4 alkylene, further a C1-C3 alkylene, further a C2-C3 alkylene, further a C3 alkylene.
   J] The composition of any one of A]-I] above, wherein, for component a, Structure 2, R4 is a C1-C5 alkyl, further a C1-C4 alkyl, further a C1-C3 alkyl, further a C1-C2 alkyl, further a C1 alkyl.
   K] The composition of any one of A]-J] above, wherein component a is selected from Structures 1a), 2a) or 3aa) as shown below:

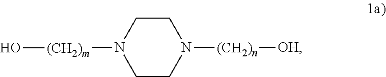

wherein n is an integer from 1 to 6, further from 1 to 5, further from 1 to 4, further from 2 to 4, further from 2 to 3, further 2; and m is an integer from 1 to 6, further from 1 to 5, further from 1 to 4, further from 2 to 4, further from 2 to 3, further 2; and further n=m;

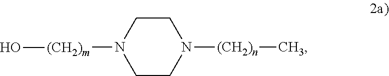

wherein n is an integer from 0 to 5, further from 0 to 4, further from 0 to 3, further from 0 to 2, further from 0 to 1, further 0; and m is an integer from 1 to 6, further from 1 to 5, further from 1 to 4, further from 2 to 4, further from 2 to 3, further 3; or
3aa) a mixture of Structure 1a) and Structure 2a).
   L] The composition of K] above, wherein component a is selected from Structure 1a), as shown above, and further n=m, further n=m=2 or 3, further n=m=2.
   M] The composition of K] above, wherein component a is selected from Structure 2a), as shown above, and further n=0 or 1, further n=0; and further m=2 or 3, further m=3.
   N] The composition of K] above, wherein component a is selected from Structure 3aa), as shown above.
   O] The composition of any one of A]-L] above, wherein component a is selected from Structure 1.
   P] The composition of any one of A]-K] or M] above, wherein component a is selected from Structure 2.
   Q] The composition of any one of A]-K] or N] above, wherein component a is selected from a mixture of Structure 1 and Structure 2.
   R] The composition of Q] above, wherein Structure 1 is selected from Structure 1a), as shown above, and further n=m, further n=m=2 or 3, further n=m=2.
   S] The composition of Q] or R] above, wherein Structure 2 is selected from Structure 2a), as shown above, and further n=0 or 1, further n=0; and further m=2 or 3, further m=3.
   T] The composition of any one of A]-S] above, wherein, for component a, Structure 1 or Structure 2, each independently has a molecular weight≥130, or ≥135, or ≥140, or ≥145, or ≥150 or ≥155 g/mol.
   U] The composition of any one of A]-T] above, wherein, for component a, Structure 1 or Structure 2, each independently has a molecular weight≤400, or ≤350, or ≤300, or ≤280, or ≤260, or ≤240, or ≤220, or ≤210, or ≤205, or ≤200, or ≤195, or ≤190, or ≤185, or ≤180 or ≤175 g/mol.
   V] The composition of any one of A]-U] above, wherein, for component b, Structure 3 and Structure 4, each n is independently from 1 to 10, further from 1 to 8, further from 1 to 6, further from 1 to 4, further from 2 to 4, further from 2 to 3, further 2.
   W] The composition of any one of A]-V] above, wherein, for component b, Structure 3 and Structure 4, each X is independently an alkyl, and further a C1-C6 alkyl, further a C1-C5 alkyl, further a C2-C5 alkyl, further a C2-C4 alkyl, further a C3-C4 alkyl, further a C4 alkyl.
   X] The composition of any one of A]-W] above, wherein, for component b, Structure 3 and Structure 4, each R1 and R2 independently meet the following relationship: R1=R2, and further R1=R2=H.
   Y] The composition of any one of A]-V] or X] above, wherein component b is selected from Structure 3; and further X is hydrogen or an alkyl or a C5-C8 aryl, when n>1; and X is an alkyl or a C5-C8 aryl, when n=1; and further X is hydrogen or an alkyl, when n>1; and X is an alkyl, when n=1
   Z] The composition of Y] above, wherein component b is selected from Structure (3a) below:

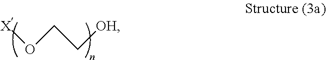

wherein n≥1; and X′ is hydrogen or an alkyl, when n>1; and X′ is an alkyl, when n=1.
A2] The composition of Y] or Z] above, wherein X′ is an alkyl.
B2] The composition of any one of Y]-A2] above, wherein component b is selected from Structure (3b) below:

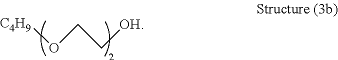

C2] The composition of any one of A]-V] or X] above, wherein component b is selected from Structure 4; and further X is hydrogen or an alkyl or a C5-C8 aryl, when n>1; and X is an alkyl or a C5-C8 aryl, when n=1; and further X is hydrogen or an alkyl, when n>1; and X is an alkyl, when n=1.
D2] The composition of C2] above, wherein component b is selected from Structure (4a) below:

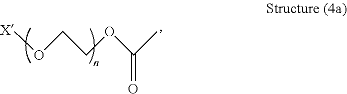

wherein n≥1; and X′ is hydrogen or an alkyl, when n>1; and X′ is an alkyl, when n=1.
E2] The composition of C2] or D2] above, wherein X′ is an alkyl.
F2] The composition of any one of C2]-DE] above, wherein component b is selected from Structure (4b) below:

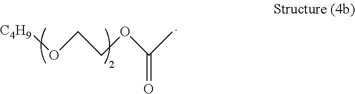

G2] The composition of any one of A]-X] above, wherein component b is selected from a mixture of Structure 3 and Structure 4.
H2] The composition of G2] above, wherein component b is selected from a mixture of Structure (3a) and Structure (4a), each as described above, and further each X′ is independently an alkyl.
I2] The composition of G2] or H2] above, wherein component b is selected from a mixture of Structure (3b) and Structure (4b), each as described above.
J2] The composition of any one of A]-I2] above, wherein, for component b, Structure 3 and Structure 4 each independently has a molecular weight≥130, or ≥135, or ≥140, or ≥145, or ≥150, or ≥155, or ≥160 g/mol.
K2] The composition of any one of A]-J2] above, wherein for component b, Structure 3 and Structure 4 each independently has a molecular weight≤350, or ≤300, or ≤250, or ≤200, or ≤195, or ≤190, or ≤185, or ≤180, or ≤175, or ≤170, or ≤165 g/mol.
L2] The composition of any one of A]-K2] above, wherein the ratio of the molecular weight of Structure 1 or Structure 2 of component a to the molecular weight of Structure 3 or Structure 4 of component b is each, independently, ≥0.80, or ≥0.85, or ≥0.90, or ≥0.95.
M2] The composition of any one of A]-L2] above, wherein the ratio of the molecular weight of Structure 1 or Structure 2 of component a to the molecular weight of Structure 3 or Structure 4 of component b is each, independently, ≤2.00, or ≤1.80, or ≤1.60, or ≤1.55, or ≤1.50, or ≤1.45, or ≤1.40, or ≤1.35, or ≤1.30, or ≤1.25, or ≤1.20, or ≤1.15, or ≤1.10.
N2] The composition of any one of A]-M2] above, wherein the weight ratio of component a to component b is ≥0.40, or ≥0.45, or ≥0.50, or ≥0.55, or ≥0.60, or ≥0.65.
O2] The composition of any one of A]-N2] above, wherein the weight ratio of component a to component b is ≤1.00, or ≤0.95, or ≤0.90, or ≤0.85, or ≤0.80, or ≤0.75, or ≤0.70.
P2] The composition of any one of A]-02] above, wherein the component a is present in an amount ≥1.0 wt %, or ≥2.0 wt %, or ≥3.0 wt %, or ≥4.0 wt %, or ≥5.0 wt %, based on the weight of the composition.
Q2] The composition of any one of A]-P2] above, wherein the component a is present in an amount ≤30 wt %, or ≤25 wt %, or ≤20 wt %, or ≤18 wt %, or ≤16 wt %, or ≤14 wt %, or ≤12 wt %, based on the weight of the composition.
R2] The composition of any one of A]-Q2] above, wherein the component a is present in an amount ≥6.0 wt %, or ≥8.0 wt %, or ≥10 wt %, or ≥11 wt %, or ≥12 wt %, based on the weight of the composition.
S2] The composition of any one of A]-R2] above, wherein the component a is present in an amount ≤30 wt %, or ≤28 wt %, or ≤26 wt %, or ≤24 wt %, or ≤22 wt %, or ≤20 wt % based on the weight of the composition.
T2] The composition of any one of A]-S2] above, wherein the component b is present in an amount ≥10 wt %, or ≥11 wt %, or ≥12 wt %, or ≥13 wt %, or ≥14 wt %, or ≥15 wt %, or ≥16 wt %, based on the weight of the composition.
U2] The composition of any one of A]-T2] above, wherein the component b is present in an amount ≤40 wt %, or ≤35 wt %, or ≤30 wt %, or ≤25 wt %, or ≤22 wt %, or ≤21 wt %, or ≤20 wt %, or ≤19 wt %, or ≤18 wt %, based on the weight of the composition.
V2] The composition of any one of A]-U2] above, wherein the component c is present in an amount ≥50 wt %, or ≥55 wt %, or ≥60 wt %, or ≥62 wt %, or ≥64 wt %, or ≥66 wt %, or ≥68 wt %, based on the weight of the composition.
W2] The composition of any one of A]-V2] above, wherein the component c is present in an amount ≤80 wt %, or ≤78 wt %, or ≤76 wt %, or ≤74 wt %, or ≤72 wt %, or ≤70 wt %, based on the weight of the composition.
X2] The composition of any one of A]-W2] above, wherein the weight ratio of component c to component a is ≥2.0, or ≥2.5, or ≥3.0, or ≥4.0, or ≥4.5, or ≥5.0, or ≥5.2, or ≥5.4, or ≥5.6.
Y2] The composition of any one of A]-X2] above, wherein the weight ratio of component c to component a is ≤8.0, or ≤7.5, or ≤7.0, or ≤6.8, or ≤6.6, or ≤6.4, or ≤6.2, or ≤6.0, or ≤5.9, or ≤5.8.
Z2] The composition of any one of A]-Y2] above, wherein the weight ratio of component c to component b is ≥1.0, or ≥1.5, or ≥2.0, or ≥2.5, or ≥3.0, or ≥3.2, or ≥3.4, or ≥3.6, or ≥3.7, or ≥3.8.
A3] The composition of any one of A]-Z2] above, wherein the weight ratio of component c to component b is ≤5.0, or ≤4.8, or ≤4.6, or ≤4.4, or ≥4.2, or ≤4.1, or ≤4.0.
B3] The composition of any one of A]-A3] above, wherein the sum of component a and component b is present in an amount ≥15 wt %, or 18 wt %, or ≥20 wt %, or 22 wt %, or ≥24 wt %, or ≥25 wt %, or ≥26 wt %, or ≥27 wt %, or ≥28 wt %, or ≥30 wt %, or ≥31 wt %, or ≥32 wt % based on the weight of the composition.
C3] The composition of any one of A]-B3] above, wherein the sum of component a and component b is present in an amount ≤50 wt %, or ≤48 wt %, or ≤45 wt % or ≤42 wt %, or ≤40 wt %, or ≤38 wt %, or ≤36 wt %, or ≤34 wt %, based on the weight of the composition.
D3] The composition of any one of A]-C3] above, wherein the sum of components a, b and c is present in an amount ≥90 wt %, or 92 wt %, or ≥94 wt %, or ≥96 wt %, based on the weight of the composition.
E3] The composition of any one of A]-D3] above, wherein the sum of components a, b and c is present in an amount ≤100 wt %, or ≤99 wt %, or ≤98 wt %, based on the weight of the composition.
F3] The composition of any one of A]-E3] above, wherein the wt % of component c≥wt % of component b≥wt % of component a, and each wt % is based on the weight of the composition.
G3] The composition of any one of A]-F3] above, wherein the wt % of component c≥wt % of component b≥wt % of component a, and each wt % is based on the weight of the composition.
H3] The composition of any one of A]-G3] above, wherein the composition comprises ≤1.0 ppm, or ≤0.50 ppm, or ≤0.20 ppm, or ≤0.10 ppm, or ≤0.05 ppm, or ≤0.02 ppm, or ≤0.01 ppm of a surfactant, based on the weight of the composition, and further the composition does not comprise a surfactant.
I3] The composition of any one of A]-H3] above, wherein the composition comprises ≤1.0 ppm, or ≤0.50 ppm, or ≤0.20 ppm, or ≤0.10 ppm, or ≤0.05 ppm, or ≤0.02 ppm, or ≤0.01 ppm, based on the weight of the composition, of a cyclodextrin or derivative thereof (for example, (2-hydroxypropyl)-beta-cyclodextrin, alpha-cyclodextrin-6-phosphorylated sodium salt, or beta-cyclodextrin monophosphate sodium salt), and further the composition does not comprise a cyclodextrin or derivative thereof.
J3] The composition of any one of A]-I3] above, wherein the composition comprises ≤1.0 ppm, or ≤0.50 ppm, or ≤0.20 ppm, or ≤0.10 ppm, or ≤0.05 ppm, or ≤0.02 ppm, or ≤0.01 ppm of an ethylamine, based on the weight of the composition, and further the composition does not comprise an ethylamine.
K3] The composition of any one of A]-J3] above, wherein the composition comprises ≤1.0 ppm, or ≤0.50 ppm, or ≤0.20 ppm, or ≤0.10 ppm, or ≤0.05 ppm, or ≤0.02 ppm, or ≤0.01 ppm of an alkylamine, based on the weight of the composition, and further the composition does not comprise an alkylamine.
L3] The composition of any one of A]-K3] above, wherein the composition comprises ≤1.0 ppm, or ≤0.50 ppm, or ≤0.20 ppm, or ≤0.10 ppm, or ≤0.05 ppm, or ≤0.02 ppm, or ≤0.01 ppm, based on the weight of the composition, of an alkanolamine (for example, monoethanol amine), and further the composition does not comprise an alkanolamine.
M3] The composition of any one of A]-L3] above, wherein the composition comprises ≤1.0 ppm, or ≤0.50 ppm, or ≤0.20 ppm, or ≤0.10 ppm, or ≤0.05 ppm, or ≤0.02 ppm, or ≤0.01 ppm, based on the weight of the composition, of a fluoride compound (for example, ammonium fluoride, ammonium bifluoride, hydrogen fluoride, a tetraalkylammonium difluoride, an alkyl phosphonium difluoride, or triethylamine trihydrofluoride), and further the composition does not comprise a fluoride compound.
N3] The composition of any one of A]-M3] above, wherein the composition comprises ≤1.0 ppm, or ≤0.50 ppm, or ≤0.20 ppm, or ≤0.10 ppm, or ≤0.05 ppm, or ≤0.02 ppm, or ≤0.01 ppm, based on the weight of the composition, of an amide (for example, N,N-dimethyl-propanamide or N-methylformamide), and further the composition does not comprise an amide.
O3] The composition of any one of A]-N3] above, wherein the composition comprises ≤1.0 ppm, or ≤0.50 ppm, or ≤0.20 ppm, or ≤0.10 ppm, or ≤0.05 ppm, or ≤0.02 ppm, or ≤0.01 ppm, based on the weight of the composition, of a quaternary ammonium compound (for example, tetramethylammonium hydroxide, tetraethylammonium hydroxide, tetrapropylammonium hydroxide, or tetrabutyl-ammonium hydroxide), and further the composition does not comprise a quaternary ammonium compound.
P3] The composition of any one of A]-03] above, wherein the composition has an “a photoresist removal time”≤50 sec, or ≤49 sec, or ≤48 see, or ≤47 see, or ≤46 sec, or ≤45 sec (see experimental section, no aging of the composition).
Q3] The composition of any one of A]-P3] above, wherein the composition has an “a photoresist removal time”≥5.0 sec, or ≥10 sec, or ≥15 sec (see experimental section, no aging of the composition).
R3] The composition of any one of A]-Q3] above, wherein the composition has an “a Cu ion concentration”≤1.2 ppm, or ≤1.1 ppm, or ≤1.0 ppm, or ≤0.90 ppm, or ≤0.80 ppm, or ≤0.60 ppm, or ≤0.40 ppm, or ≤0.30 ppm, or ≤0.20 ppm (see experimental section, 54° C. for 30 minutes, no aging of the composition).
S3] The composition of any one of A]-R3] above, wherein the composition has an “a Cu ion concentration”≥0, or ≥0.1 ppm (see experimental section, 54° C. for 30 minutes, no aging of the composition).
T3] The composition of any one of A]-S3], wherein the composition is a photoresist stripping composition.
A4]A process to form the composition of any one of A]-T3], the process comprising mixing at least components a and b.
B4] The process of A4] above, wherein the process comprises mixing at least components a, b and c.
C4] The process of A4] or B4], wherein the mixing takes place at a temperature from ≥18° C., or ≥19° C., or ≥20° C. and/or ≤27° C., or ≤26° C., or ≤25° C. or ≤24° C., or ≤23° C.
D4] The process of any one of A4]-C4], wherein the mixing takes at ambient atmosphere.
E4]A process to remove a photoresist, the process comprising applying to the surface of the photoresist, the composition of any one of A]-T3] above.
F4] The process of E4] above, wherein the photoresist is coated onto a metal surface.
G4] The process of F4] above, wherein the metal of the metal surface is selected from steel, stainless steel, brass, chrome, titanium, molybdenum, aluminum, aluminum alloy, copper, copper alloy, silver or gold.
H4] The process of any one of E4]-G4] above, wherein the temperature of the composition is ≥18° C., or ≥19° C., or ≥20° C., or ≥22° C. and/or ≤30° C., or ≤29° C., or ≤28° C., or ≤27° C., or ≤26° C. C or ≤25° C., or ≤24° C., when applied to the surface of the photoresist.

### EXPERIMENTAL

Reagents are listed in Table 1, and boiling points for N,N′-di(2-hydroxyethyl) piperazine are listed in Table 1b. Compositions are shown in Table 2a through Table 2d below. For each composition, the components (amine and/or glycol ether and/or water) were mixed together at room temperature and ambient atmosphere. A homogeneous, transparent solution resulted, which was stable at room temperature.

TABLE 1a
Reagents

| Ingredient | Product Name | Chemical Description, Chemical formula, or Structure |
|---|---|---|
| Amine 1 | N,N′-di(2-hydroxyethyl) piperazine | 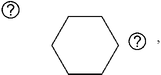 |
| | | BP = 300° C. at 760 mm Hg, MW = 174.24 |
| | | g/mol, available from Sinopharm Chemical |
| | | Reagent Co., Ltd. (SCR) |
| Amine 2 | N,N′-di(2-hydroxyethyl) piperazine | 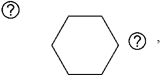 |
| | | BP = 300° C. at 760 mm Hg, MW = 174.24 g/mol |
| Amine 3 | N-methyl-N′-3-hydroxy- propyl piperazine (MHPP) | 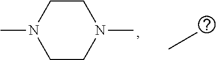 |
| | | BP = 253° C. at 760 mm Hg, MW = 158.24 g/mol |
| | | available from SCRC |
| Amine 4 | Monoisopropanolamine | NH₂CH₂CH(OH)CH₃, available from |
| | (MIPA) | The Dow Chemical Company (DOW), |
| | | BP = 159° C. at 760 mm Hg |
| Amine 5 | Aminoethylethanolamine | NH₂CH₂CH₂NHCH₂CH₂OH |
| | (AEEA) | BP = 243° C. at 760 mm Hg), available from DOW |
| Amine 6 | Hydroxyethyl piperazine | NH(CH₂CH₂)₂NCH₂CH₂OH |
| | (HEP) | (BP = 246° C. at 760 mm Hg), available from SCRC |
| Amine 7 | N-(3-aminopropyl)- | NH₂CH₂CH₂CH₂N(CH₂CH₂)₂O |
| | morpholine (NAPM) | (BP = 224° C. at 760 mm Hg), available from SCRC |
| Diethylene | Glycol Ether | CH₃CH₂CH₂CH₂(OCH₂CH₂)₂OH |
| glycol | | (BP = 230° C. at 760 mm Hg), MW = 162.23 g/mol, |
| butyl ether | | available from DOW |
| Octaethylene | Glycol Ether | CH₃CH₂CH₂CH₂(OCH₂CH₂)₈OH |
| glycol butyl | | ( BP = 492° C. at 760 mm Hg), MW = 426.5 g/mol, |
| ether | | |
| Ethylene glycol | Glycol Ether | CH₃CH₂CH₂OCH₂CH₂OH |
| propyl ether | | (BP = 151° C. at 760 mm Hg), MW = 104.15 g/mol, |
| | | available from DOW |

*Predicted Boiling Point-see SciFinder CAS Registry Number 80744-48-5 (2023); note an average predicted BP reported (492.1 ± 40.0° C.).

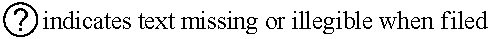

TABLE 1b
Boiling for N,N′-Di(2-hydroxyethyl) piperazine

| | | boiling | |
|---|---|---|---|
| | pressure | point | |
| | (mm Hg) | degree C. | source |
| Experimental | 50 | 220 | (1) Pyman, F. L.; Journal of the Chemical Society, |
| | | | Transactions, (1908), 93, 1793-1807, CAplus |
| Experimental | 12 | 190 | (3) Demarcq, Michel Charles; Compt. rend., (1961), |
| | | | 252, 3454-6, CAplus |
| Experimental | 10 | 180 | (4) Gold-Aubert, Ph.; Helvetica Chimica Acta, (1959), |
| | | | 42, 1156-9, CAplus |
| Experimental | 7 | 165 | (5) Dell, H. D.; Naturwissenschaften, (1966), |
| | | | 53(16), 405, CAplus |
| Predicted | 760 | 305 | (1) Calculated using Advanced Chemistry Development |
| Extrapolated* | 760 | 294 | (ACD/Labs) Software V11.02 ( ©1994-2023 ACD/Labs) |
| | | | extrapolated based on the equation in the plot |
| Average** | 760 | 300 | |

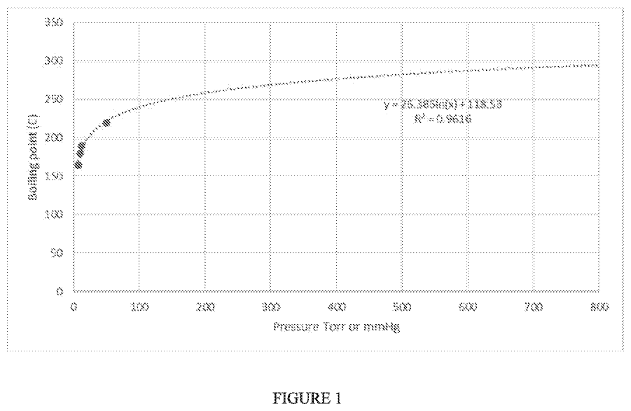

*See FIG. 1.
**Average = [(Predicted + Extrapolated)/2]

TABLE 2a
Compositions

| | SI Units | CE1 | CE2 | CE3 | CE4 | CE5 | CE6 | CE7 | CE8 |
|---|---|---|---|---|---|---|---|---|---|
| Amine 4 | wt % | 12 | 20 | | | 30 | 30 | 50 | |
| Amine 5 | wt % | | | 12 | 20 | | | | 30 |
| Diethylene glycol | wt% | 18 | 30 | 18 | 30 | 70 | | 50 | 70 |
| butyl ether | | | | | | | | | |
| Water | wt % | 70 | 50 | 70 | 50 | | 70 | | |
| BP(Amine) | ° C. | 159 | 159 | 243 | 243 | 159 | 159 | 159 | 243 |
| BP(Amine)/BP(Glycol)* | | 0.688 | 0.688 | 1.05 | 1.05 | 0.688 | 0.688 | 0.688 | 1.05 |

*Note,
the BP(Glycol) is the BP of the glycol ether in the above table and the tables below.

TABLE 2b
Compositions

| | SI Units | CE9 | CE10 | CE11 | CE12 |
|---|---|---|---|---|---|
| Amine 6 | wt % | 12 | 20 | | |
| Amine 7 | wt % | | | 12 | 20 |
| Diethylene glycol | wt % | 18 | 30 | 18 | 30 |
| butyl ether | | | | | |
| Water | wt % | 70 | 50 | 70 | 50 |
| BP(Amine) | ° C. | 215 | 215 | 244 | 244 |
| BP(Amine)/BP(Glycol) | | 0.931 | 0.931 | 1.06 | 1.06 |

TABLE 2c
Compositions

| | SI Units | IE1 | IE2 | CE13 | CE20 | CE14 | CE15 | IE3 |
|---|---|---|---|---|---|---|---|---|
| Amine 1 | wt % | 12 | | 30 | | | | |
| Amine 2 | | | | | | | | 12 |
| Amine 3 | wt % | | 12 | | 30 | 30 | 50 | |
| Diethylene glycol | wt % | 18 | 18 | | 70 | | | 18 |
| butyl ether | | | | | | | | |
| Water | wt % | 70 | 70 | 70 | | 70 | 50 | 70 |
| BP(Amine) | ° C. | 300 | 253 | 300 | 253 | 253 | 253 | 300 |
| BP(Amine)/ | | 1.30 | 1.10 | undefined | 1.10 | undefined | undefined | 1.30 |
| BP(Glycol) | | | | | | | | |

TABLE 2d
Compositions

| | SI Units | CE16 | CE17 | CE18 | CE19 | IE5 | IE6 |
|---|---|---|---|---|---|---|---|
| Amine 1 | wt % | 12 | 20 | 12 | 20 | 12 | |
| Amine 3 | | | | | | | 12 |
| octaethylene glycol butyl ether | wt % | 18 | 30 | | | | |
| ethylene glycol propyl ether | wt % | | | 18 | 30 | | |
| Diethylene glycol | | | | | | 18 | 18 |
| butyl ether | | | | | | | |
| Water | wt % | 70 | 50 | 70 | 50 | 70 | 70 |
| BP(Amine) | ° C. | 300 | 300 | 300 | 300 | 300 | 253 |
| BP(Amine)/BP(Glycol) | | 0.610 | 0.610 | 1.99 | 1.99 | 1.30 | 1.10 |

### Photoresist Stripping:

SFP-1400 photoresist solution (2 mL, from Merck) was dropped onto the surface of glass substrate (indium tin oxide coated soda lime glass from Corning) with a size of “100 mm×100 mm×1 mm.” The substrate was spun at a rotation speed of 500 rpm for 10 seconds (model LabSpin 6/8, SSUS MicroTech), under ambient atmosphere, to spin-coat the photoresist solution. Then rotation speed was accelerated to 1000 rpm, and maintained for 30 seconds, to obtain a spin-coated substrate with a “1 μm thickness” of a photoresist film (as measured by a model Filmetrics F50, Unicorn, laser thickness meter). The spin-coated substrate was heated at 130° C. (set temp.) (hot plate in a nitrogen atmosphere) for 10 minutes, to evaporate the solvent completely and curve the photoresist film, to form a baked substrate.

In the following stripping step, each composition (30 g, see Tables 2a through 2d) was prepared in a container with an edge length (perimeter of a cube) over 100 mm (volume of the container was 1 L). The baked substrate was put into the container at 22° C., and immediately shaking was applied to the container—by hand, two front and back shakes per second. The time was recorded for completely removing the photoresist from the substrate during the shaking process. The less time required to strip (remove) the photoresist, the better the performance of the composition. For each composition—three stripping tests were conducted, and a range of time reported. Results are shown in Table 3 and Table 4 below.

Note, for each composition of Table 4, the composition was aged at 54° C. for six hours, in air. Then the above photoresist stripping process was applied as described above.

### Metal Corrosion:

A highly pure copper foil (Alfa Aesar, copper foil with 99.999% purity), with a calendaring thickness of 1 mm, was cut into squares, and each square had a weight of 0.90±0.01 g. A copper oxide (CuO or Cu₂O) passivation layer was formed (during storage) on the surface of the copper foil. Thus, the cut copper pieces were immersed in a 5% HCl aqueous solution for five minutes, in order to completely remove the passivation layer and guarantee the 99.999% purity (as provided by supplier). The “acid polished” copper pieces were rinsed with 20 ml of DI water (deionized water), and dried under a nitrogen gas flow. For each composition, a clean copper piece was put into a 10 mL glass bottle containing 5 g of the composition. The bottle was stored at 54° C. for 30 minutes (corrosion test). After this time, the copper piece was removed from the bottle, and the remaining composition was examined by ICP-OES (Inductively Coupled Plasma-Optical Emission Spectrometry) using a model Optima 5300DV, from Perkin Elmer. This spectrometry was used to determine the content of copper ions remaining in the composition. The smaller the concentration of the copper ions in the composition, the better the composition, in terms of preserving the copper foil. For each composition, one test sample was analyzed, and the ICP-OES measurement was repeated three times, and an average concentration value was reported. Results are shown in Table 4, Table 5a and Table 5b below.

Note, for each composition of Table 4, before the composition was added to the “10 ML glass bottle,” the composition was aged at 54° C. for six hours, in air. Then, the composition was added to the bottle, and the corrosion test was conducted as described above.

TABLE 3
Photoresist Stripping Test

| | CE1 | CE2 | CE3 | CE4 | CE9 | CE10 | CE11 | CE12 | IE1 | IE2 | IE3 | CE16** | CE17** | CE20 |
|---|---|---|---|---|---|---|---|---|---|---|---|---|---|---|
| Time | 40- | 60- | 45- | 65- | 50- | 110- | 55- | 115- | 40- | 35- | 40- | 110- | 125- | 60- |
| required to | 45 | 65 | 50 | 70 | 55 | 115 | 60 | 120 | 45 | 40 | 45 | 115 | 130 | 65 |
| strip | | | | | | | | | | | | | | |
| photoresist* | | | | | | | | | | | | | | |
| (sec) | | | | | | | | | | | | | | |

*Photoresist removal time.
**BP ratio (Amine/Glycol) = 0.610.

TABLE 4
Additional Studies

| | CE18 | CE19 | IE5 | IE6 |
|---|---|---|---|---|
| Time required to strip* | 120-125 | >180 seconds | 55-60 | 65-70 |
| | seconds | (fail) | seconds | seconds |
| Cu ion conc. (ppm)** | 0.3 | 0.2 | 0.2 | 0.8 |
| BP ratio | 1.99 | 1.99 | 1.30 | 1.10 |
| (Amine/Glycol) | | | | |

*Photoresist removal time.
**Each ppm based on the total weight of the solution at the end of the corrosion test.

TABLE 5a
Metal (Copper) Corrosion Test

| | CE1 | CE3 | CE5 | CE6 | CE7 | CE8 | CE9 | CE10 | CE11 | CE12 |
|---|---|---|---|---|---|---|---|---|---|---|
| Cu ion conc. | 8.8 | 1.7 | 6.6 | 8.9 | 3.8 | 2.0 | 1.3 | 2.8 | 1.1 | 2.3 |
| (ppm)* | | | | | | | | | | |

*Each ppm based on the total weight of the solution at the end of the corrosion test.

TABLE 5b
Metal (Copper) Corrosion Test

| | IE1 | IE2 | CE13 | CE20 | CE14 | CE15 | CE16 | CE17 | IE3 |
|---|---|---|---|---|---|---|---|---|---|
| Cu ion conc. | ND** | 0.3 | 1.6 | 1.3 | 0.5 | 0.3 | 0.1 | 0.1 | ND** |
| (ppm)* | | | | | | | | | |

*Each ppm based on the total weight of the solution at the end of the corrosion test.
**Not Detectable

As seen in Table 3, the photoresist stripping performance of each of compositions IE1, IE2 and IE3 outperformed compositions CE2, CE3, CE4, CE9, CE10, CE11, CE12, CE16, CE17 and CE20. The photoresist stripping performance of each of compositions IE1, IE2 and IE3 was comparable to, or better than, CE1. As seen in Table 4, the photoresist stripping performance of each of compositions IE5 and IE6 outperformed compositions CE18 and CE 19. It is noted that the compositions that contain an amine with a BP≥250° C., but have a BP(Amine)/BP(Glycol) ratio that falls outside the noted ratio from 0.70 to 1.9, had longer photoresist strip times. Compositions IE1, IE2 and IE3 had very low or no detectable metal leaching, in the liquid phase during the corrosion process, as compared to CE1, CE3 CE5 through CE14 and CE20 (see Tables 5a and 5b).

1. A composition comprising at least the following components a), b) and c):
a) at least one N-substituted piperazine selected from the following Structures 1, 2 or a mixture thereof: 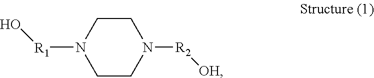
wherein R1 and R2 are each independently a C1-C6 alkylene; 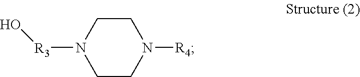
wherein R3 is a C1-C6 alkylene and R4 is a C1-C6 alkyl
b) at least one glycol ether selected from the following Structures 3, 4 or a mixture thereof: 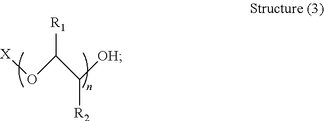
wherein n≥1; R1 is hydrogen or an alkyl; R2 is hydrogen or an alkyl; X is hydrogen or an alkyl or an aryl, when n>1; and X is an alkyl or an aryl, when n=1; 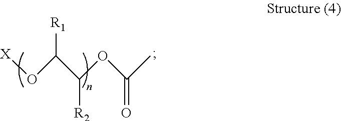
wherein n≥1; R1 is hydrogen or an alkyl; R2 is hydrogen or an alkyl; X is hydrogen or an alkyl or an aryl, when n>1; and X is an alkyl or an aryl, when n=1;
c) water.

2. The composition of claim 1, wherein for component a, Structure 1 or Structure 2, each independently has a boiling point (at 760 mm Hg)≥250° C.

3. The composition of claim 1, wherein the ratio of the boiling point (760 mm Hg) of Structure 1 or Structure 2 of component a to the boiling point (760 mm Hg) of Structure 3 or Structure 4 of component b, is each, independently, ≥0.70.

4. The composition of claim 1, wherein the ratio of the boiling point (760 mm Hg) of Structure 1 or Structure 2 of component a to the boiling point (760 mm Hg) of Structure 3 or Structure 4 of component b, is each, independently, ≤1.9.

5. The composition of claim 1, wherein, for component a, Structure 1, R1=R2.

6. The composition of claim 1, wherein component a is selected from
Structures 1a), 2a) or 3aa), each as shown below: 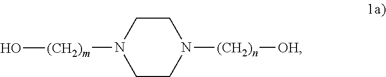
wherein n is an integer from 1 to 6; and m is an integer from 1 to 6; 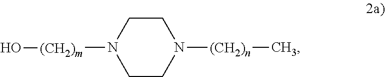
wherein n is an integer from 0 to 5; and m is an integer from 1 to 6; or
3aa) a mixture of Structure] a) and Structure 2a).

7. The composition of claim 6, wherein component a is selected from Structure 1a).

8. The composition of claim 6, wherein component a is selected from Structure 2a).

9. The composition of claim 6, wherein component a is selected from Structure 3aa).

10. The composition of claim 1, wherein for Structure 3 or Structure 4 of component b, each n is independently from 1 to 10.

11. The composition of claim 1, wherein for Structure 3 or Structure 4 of component b, each X is independently an alkyl.

12. The composition of claim 1, wherein component b is selected from Structure (3a) below: 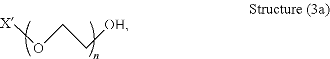
wherein n≥1; and X′ is hydrogen or an alkyl, when n>1; and X′ is an alkyl, when n=1.

13. The composition of claim 1, wherein component b is selected from Structure (4a) below: 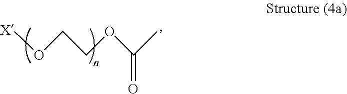
wherein n≥1; and X′ is hydrogen or an alkyl, when n>1; and X′ is an alkyl, when n=1.

14. The composition of claim 1, wherein the sum of components a, b and c is present in an amount from 90 wt % to 100 wt %, based on the weight of the composition.

15. The composition of claim 1, wherein the composition has an “a photoresist removal time”≤50 sec (see experimental section, no aging of the composition).

16. The composition of claim 1, wherein the composition has an “a Cu ion Concentration,” after 30 minutes at 54° C., ≤1.2 ppm (see experimental section, no aging of the composition).

17. The composition of claim 1, wherein the composition is a photoresist stripping composition.

18. A process to form the composition of claim 1, the process comprising mixing at least components a and b.

19. A process to remove a photoresist, the process comprising applying to the surface the photoresist, the composition of claim 1.

20. The process of claim 19, wherein the photoresist is coated onto a metal surface.
